(19) United States
(12) Patent Application Publication
(10) Pub. No.: US 2006/0205154 A1
(43) Pub. Date: Sep. 14, 2006

(54) MANUFACTURING METHOD OF AN NON-VOLATILE MEMORY STRUCTURE

(76) Inventors: Chih-Wei Hung, Hsin-chu City (TW); Cheng-Yuan Hsu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,796

(22) Filed: May 5, 2006

Related U.S. Application Data
(62) Division of application No. 10/710,671, filed on Jul. 28, 2004.

(30) Foreign Application Priority Data
Apr. 2, 2004 (TW) 93109185

(51) Int. Cl. H01L 21/336

(52) U.S. Cl. 438/257; 438/267

(57) ABSTRACT

A non-volatile memory including a substrate, a plurality of gate structures, a plurality of select gate structures, spacers and source region/drain region is provided. Each gate structure on the substrate further includes a bottom dielectric layer, an electron trapping layer, an upper dielectric layer, a control gate and a cap layer. The select gate structures are disposed on one side of the respective each gate structure. Each select gate structure includes a select gate dielectric layer and a select gate. The select gate structures and the gate structures are connected in series to form a memory cell row. The spacers are disposed between the select gate structures and the gate structures. The source region and the drain region are disposed in the substrate on each side of the memory cell row.

### CROSS-REFERENCE TO RELATED APPLICATION

This application is a divisional of a prior application Ser. No. 10/710,671, filed Jul. 28, 2004, which claims the priority benefit of Taiwan application serial no. 931 091 85, filed Apr. 2, 2004. All disclosures are incorporated herewith by reference.

### BACKGROUND OF THE INVENTION

1. Field of the Invention

The present invention relates to a semiconductor device. More particularly, the present invention relates to a non-volatile memory structure and manufacturing method thereof.

2. Description of Related Art

Electrically erasable programmable read-only memory (EEPROM) is a type of non-volatile memory. Since EEPROM allows multiple data writing, reading, erasing operations and retains stored data even after the power to the device is removed, it has been broadly applied in personal computer and electronic equipment.

A typical EEPROM device has a floating gate and a control gate formed by doped polysilicon. To prevent reading errors in the EEPROM due to over-erasure, an additional select gate is often formed on the sidewall of the control gate and the floating gate above the substrate to form a split-gate structure.

In addition, the conventional technique frequently deploys a charge-trapping layer instead of a polysilicon floating gate. The charge-trapping layer is formed by silicon nitride, for example. Furthermore, a silicon oxide layer is formed over and under the silicon nitride charge-trapping layer to produce an oxide-nitride-oxide (ONO) composite layer. FIG. 1 is a schematic cross-sectional view of an EEPROM having a split-gate structure according to U.S. Pat. No. 5,930,631.

As shown in FIG. 1, the memory cell includes a substrate 1, a field oxide layer 3, a gate oxide layer 5, a select gate 7, a drain region 9, a source region 11, an oxide-nitride-oxide (ONO) composite layer 13 and a control gate 15. The field oxide layer 3 above the substrate 1 isolates out an active region. The select gate 7 is disposed over the substrate 1. The gate oxide layer 5 is disposed between the select gate 7 and the substrate 1. The drain region 9 and the source region 11 are disposed in the substrate 1 on each side of the select gate 7. A portion of the control gate 15 is positioned right above the select gate 7 while another portion of the control gate 15 is adjacent to the source region 11. The oxide-nitride-oxide (ONO) composite layer 13 is disposed between the control gate 15 and the select gate 7 and between the control gate 15 and the substrate 1.

Because the control gate 15 occupies substrate area, a memory cell having a split gate structure will require an area bigger than a conventional stacked gate EEPROM cell. This would cause a problem in building high integration density cell arrays.

Besides, memory cells connected together as a NAND type array have a higher integration density than memory cells connected together as an NOR type array. Therefore, when the memory device is formed more compact, the split gate flash memory cells are formed as a NAND type array. However, writing/reading data of a NAND flash memory is more complicated.

Moreover, the read-out current of the memory is smaller due to a lot of memory cells are serial connected in an array. This slows down the memory running speed and affects overall electrical performance of the memory cell.

### SUMMARY OF THE INVENTION

Accordingly, the present invention is directed to a non-volatile memory structure and manufacturing method thereof capable of simplifying the fabrication of the NAND gate array of the non-volatile memory. Moreover, the non-volatile memory can be programmed using source-side injection (SSI) to increase programming speed and improve memory performance.

According to an embodiment of the invention, the non-volatile memory structure includes a substrate, a plurality of gate structures, a plurality of select gate structures, spacers and a source region/drain region. Each gate structure at least includes, in sequence from the substrate, a bottom dielectric layer, a charge-trapping layer, an upper dielectric layer, a control gate and a cap layer. The select gate structures are disposed on one side of the respective gate structures. Each select gate structure includes a select gate dielectric layer and a select gate. The select gate structures and the gate structures are connected in series to form a memory cell row. The spacers are disposed between the select gate structures and the gate structures. The source region and the drain region are disposed in the substrate on each side of the memory cell row.

In the aforementioned non-volatile memory structure, the select gate may completely fill the space between neighboring gate structures. The charge-trapping layer can be a silicon nitride layer and both the bottom dielectric layer and the upper dielectric layer can be silicon oxide layer, for example.

In the aforementioned non-volatile memory structure, a gate structure and a select gate together with an intervening spacer constitute a memory cell. Since the memory cells are connected together in series with no space separating neighboring memory cells, overall level of integration of the memory cell array is increased.

Since the charge-trapping layer may serve as a storage unit for electric charges, the gate coupling ratio concept is no longer important. Hence, the memory cell can have a lower operating voltage and a higher operating speed.

The present invention also provides an alternative non-volatile memory cell structure. The non-volatile memory cell mainly includes a substrate, a plurality of gate structures, a plurality of select gates, spacers, a select gate dielectric layer, a source region and a drain region. Each gate structure at least includes, in sequence from the substrate, a bottom dielectric layer, a charge-trapping layer, an upper dielectric layer, a control gate and a cap layer. The select gates are disposed on one side of the respective gate structures. The spacers are disposed between the gate structures and the select gates. The select gate dielectric layer is disposed between the select gates and the substrate. The source region is disposed in the substrate on that side of the select gate away from the gate structure. The drain region is disposed in the substrate on that side of the select gate away from the gate structure.

In the aforementioned non-volatile memory structure, the charge-trapping layer can be a silicon nitride layer and both the bottom dielectric layer and the top dielectric layer can be silicon oxide layer, for example. Since the charge-trapping layer may serve as a storage unit for electric charges, the gate coupling ratio concept is no longer important. Hence, the memory cell can have a lower operating voltage and a higher operating speed.

The present invention also provides a method of fabricating a non-volatile memory. First, a substrate is provided. Thereafter, a plurality of gate structures is formed on the substrate. Each gate structure includes, in sequence from the substrate, a bottom dielectric layer, a charge-trapping layer, an upper dielectric layer, a control gate and a cap layer. A plurality of spacers is formed on the respective sidewalls of the gate structures. Next, a select gate dielectric layer is formed over the substrate. A select gate is formed on one side of each gate structure so that the gate structures are connected together in series to form a memory cell row. A source region and a drain region are formed in the substrate on each side of the memory cell row. Finally, a bit line having electrical connection with the drain region is formed over the substrate.

In the aforementioned method of fabricating the non-volatile memory, the process of forming a select gate on one side of the gate structure so that the gate structures can be serially connected together to form a memory cell row includes the following steps. First, a conductive layer is formed over the substrate. The conductive layer completely fills the space between neighboring gate structures. Thereafter, the gate structure outside the area for fabricating the memory cell row and a portion of the conductive layer are removed.

In the aforementioned method of fabricating the non-volatile memory, the charge-trapping layer serves as a storage unit for electric charges and hence the gate coupling ratio is no longer critical. Thus, the memory cell can have a lower operating voltage and a higher operating speed. Furthermore, the process of fabricating the non-volatile memory in the present invention is much simpler than the conventional process so that the production cost is reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional non-volatile memory cell structure.

FIG. 2A is a top view of a NAND type non-volatile memory structure according to the present invention.

FIG. 2B is a cross-sectional view of a NAND type non-volatile memory structure according to the present invention.

FIG. 2C is a schematic cross-sectional view of a single memory cell according to the present invention.

FIG. 3 is a simplified circuit diagram of a NAND type non-volatile memory according to the present invention.

FIGS. 4A through 4E are schematic cross-sectional view showing the steps for fabricating a NAND type non-volatile memory according to one preferred embodiment of the present invention.

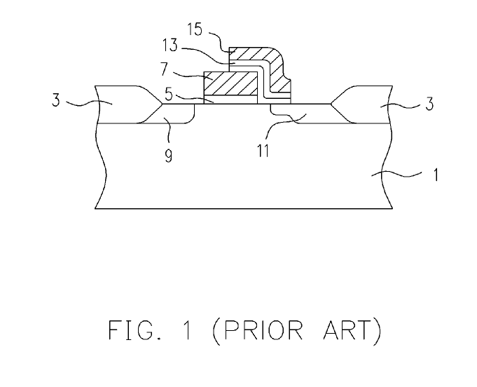

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

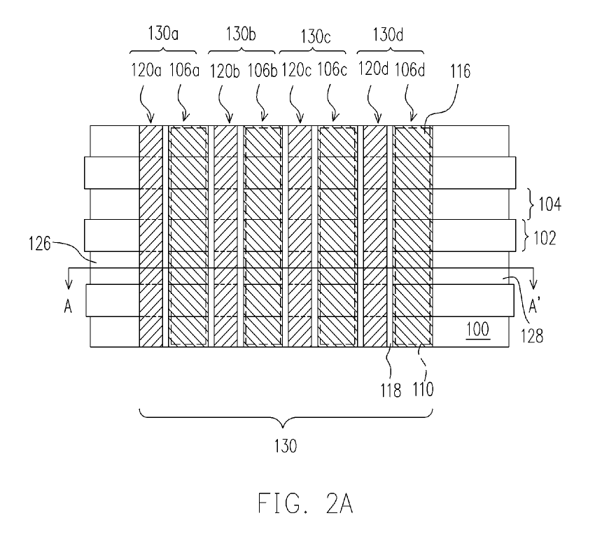

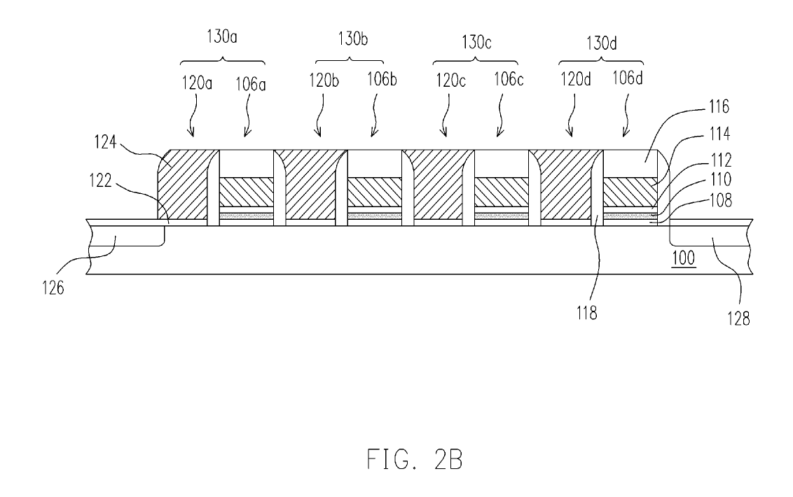

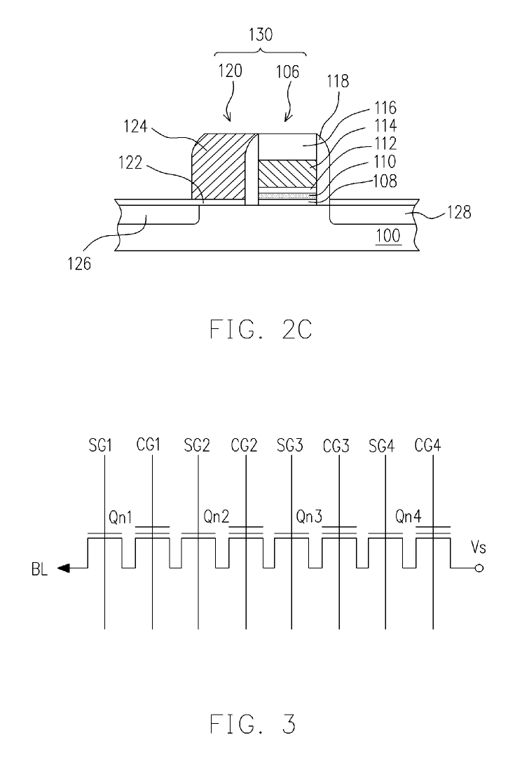

FIG. 2A is a top view of a NAND type non-volatile memory structure according to the present invention. FIG. 2B is a cross-sectional view of the NAND type non-volatile memory structure in FIG. 2A along line A-A′. FIG. 2C is a schematic cross-sectional view of a single memory cell according to the present invention. As shown in FIGS. 2A and 2B, the non-volatile memory structure of the present invention at least includes a substrate 100, a device isolation structure 102, an active region 104, a plurality of gate structures 106a˜106d, spacers 118, a plurality of select gate structures 120a˜120d, a drain region 126 and a source region 128. Each gate structure includes a bottom dielectric layer 108, a charge-trapping layer 110, an upper dielectric layer 112, a control gate 114 and a cap layer 116 from the substrate 100 sequentially. Each select gate structure includes a select gate dielectric layer 122 and a select gate 124 from the substrate 100 sequentially.

The substrate 100 is a silicon substrate, for example. The substrate 100 can be a P-type substrate or an N-type substrate. The device isolation structure 102 is disposed within the substrate 100 for defining the active region 104.

The gate structures 106a˜106d are disposed on the substrate 100. The bottom dielectric layer 108 is formed by silicon oxide and has a thickness between about 20 Å to 30 Å, for example. The charge-trapping layer 110 is formed by silicon nitride and has a thickness between about 30 Å to 50 Å, for example. The upper dielectric layer 112 is formed by silicon oxide and has a thickness between about 20 Å to 40 Å, for example. The control gate 114 is formed by a doped polysilicon and has a thickness between about 600 Å to 1000 Å, for example. The cap layer 116 is formed by a silicon oxide and has a thickness between about 1000 Å to 1500 Å, for example.

The spacers 118 are disposed on the respective sidewalls of the gate structures 106a˜106d. The spacers are formed by silicon oxide, for example.

The select gate structures 120a˜120d are disposed above the substrate 100 on one side of each of the respective gate structures 106a˜106d respectively. The select gates 120a˜120d are connected to the gate structures 106a˜106d respectively. In other words, the select gates 120a˜120d and the stacked gate structures 106a˜106d are alternately connected. The select gate dielectric layer 122 is a silicon oxide layer having a thickness between about 160 Å to 170 Å, for example. The select gate 124 is formed by a doped polysilicon, for example.

A plurality of memory cell structures 130a˜130d are formed on the locations where the gate structures 106a˜106d, the spacers 118 and the select gate structures 120a˜120d cross over the active region 104 respectively. Furthermore, the memory cell structures 130a˜130d on the active region 104 are serially connected to form a memory cell row 132. The drain region 126 is formed in the substrate 100 on the outer side the select gate structure 120a corresponding to the memory cell row 132. Similarly, the source region 128 is formed in the substrate 100 on the outer side of the gate structure 106d corresponding to the memory cell row 132. In other words, the drain region 126 and the source region 128 are disposed in the substrate 100 on each side of the memory cell row 132.

The aforementioned memory cell row 132 includes the memory cell structures 130a˜130d formed by the gate structures 106a˜106d, the spacers 118 and the select gate structures 120a˜120d on the active region 104. Since there is no gaps between the memory cells 130a˜130d, the integration density of the memory cell array is increased.

Because the charge-trapping layer 110 serves as a storage unit for electric charges, the gate-coupling ratio is no longer critical. Hence, the memory cell can have a lower operating voltage and a higher operating speed.

In the aforementioned embodiment, there are four memory cells 130a˜130d serially connected in a memory cell row. However, the actual number of serially connected memory cells may vary according to circumstances. For example, a total of 32 to 64 memory cells may be serially connected along the same bit line.

In addition, one single memory cell structure, the gate structure 106, the spacers 118, the select gate structure 120 can be disposed as shown in FIG. 2C. The drain region 126 is formed in the substrate on one side of the select gate structure 120 and the source region 128 is formed in the substrate 100 on one side of the gate structure 106. Since the charge-trapping layer 110 serves as a storage unit for electric charges, the gate-coupling ratio is no longer critical. Hence, the memory cell can have a lower operating voltage and a higher operating speed.

FIG. 3 is a simplified circuit diagram of a NAND type non-volatile memory according to the present invention. As shown in FIG. 3, the memory cell row includes four memory cells Qn1˜Qn4, select gate lines SG1˜SG4 and control gate lines CG1˜CG4. The memory cells Qn1˜Qn4 are serially connected together. The select gate lines SG1˜SG4 are connected to the select gates of the memory cells Qn1˜Qn4 respectively. The control gate lines CG1˜CG4 are connected to the control gates of the memory cells Qn1˜Qn4 respectively.

To program the memory cell, taking Qn2 for example, a bias voltage of about 5V is applied to the source terminal, a bias voltage of about 1.5V is applied to the selected select gate line SG2, a bias voltage of about 8V is applied to the non-selected select gate lines SG1, SG3, SG4, a bias voltage of about 8V is applied to the selected control gate line CG2, a bias voltage of between 5˜8V is applied to the non-selected control gate lines CG1, CG3, CG4 and a zero voltage is applied to the substrate. Then, electrons are injected into the floating gate and the memory cell Qn2 is programmed by the source-side injection (SSI) effect.

To read data from the memory cell Qn2, a zero volt is applied to the source terminal, a bias voltage of about 3.3V is applied to the select gate lines SG1˜SG4, a bias voltage of about 8V is applied to the control gate lines CG1, CG3, CG4, a bias voltage of about 3V is applied to the control gate line CG2 and a voltage of about 1.5V is applied to the drain terminal (the bit line). Because the channel of the memory cells having negative-charged charge-trapping layer is shut and has a small current while the channel of memory cells having positive-charged charge-trapping layer is open and has a large current, a data value of ‘1’ or ‘0’ can be determined according to on/off state of the channel and/or the magnitude of channel current.

To erase data from the memory cell Qn2, a bias voltage of about −10V is applied to the source terminal, the select gate lines SG1˜SG4, the control gate lines CG1˜CG4 and a zero volt is applied to the substrate so that trapped electrons are pulled out from the charge-trapping layer of the memory cell into the substrate through Fowler-Nordheim (F-N) tunneling effect.

In the operating mode of the memory cell row according to the present invention, a single bit in a single memory cell is programmed by hot carrier effect and all the data residing in the memory cell row are erased by F-N tunneling effect. With a higher electron injection rate, the memory cell row can operate at a lower operating memory cell current and a higher operating speed. A smaller current flow also means a reduction in overall power consumption by the chip.

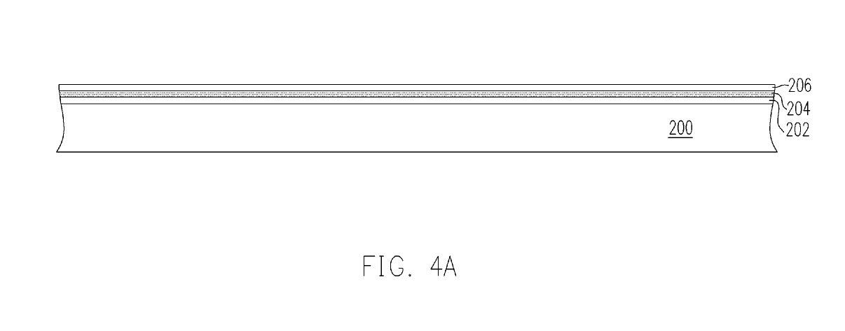

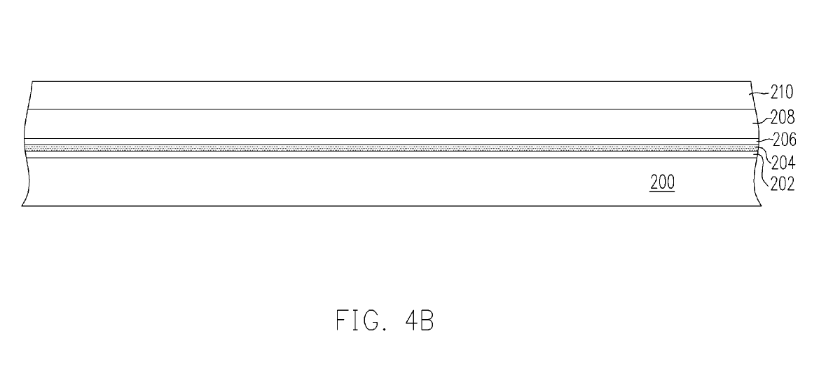

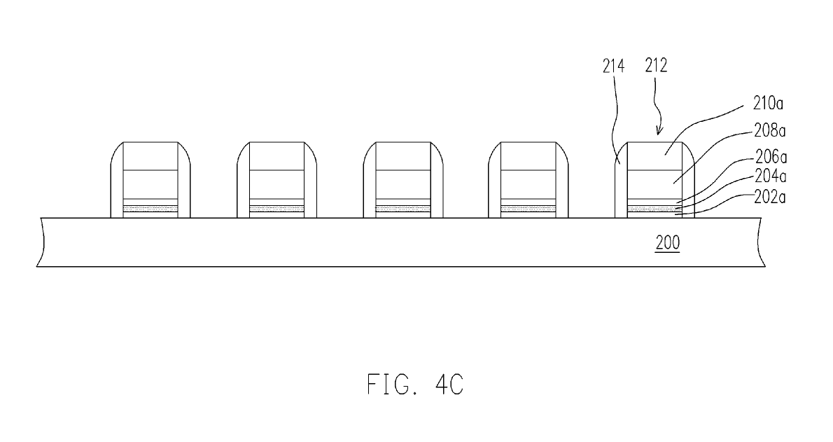

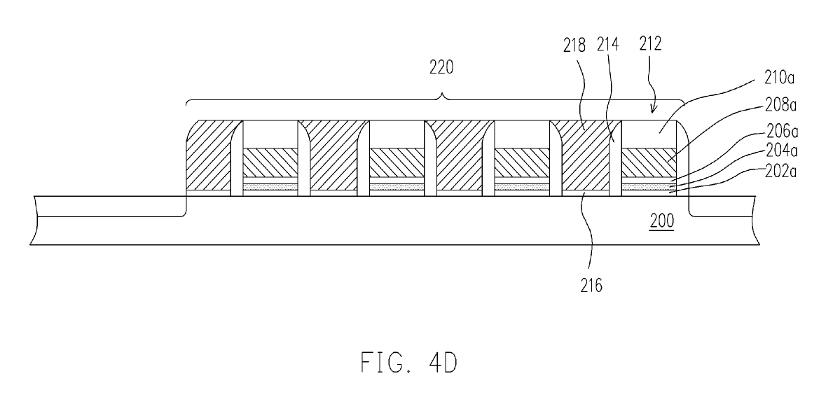

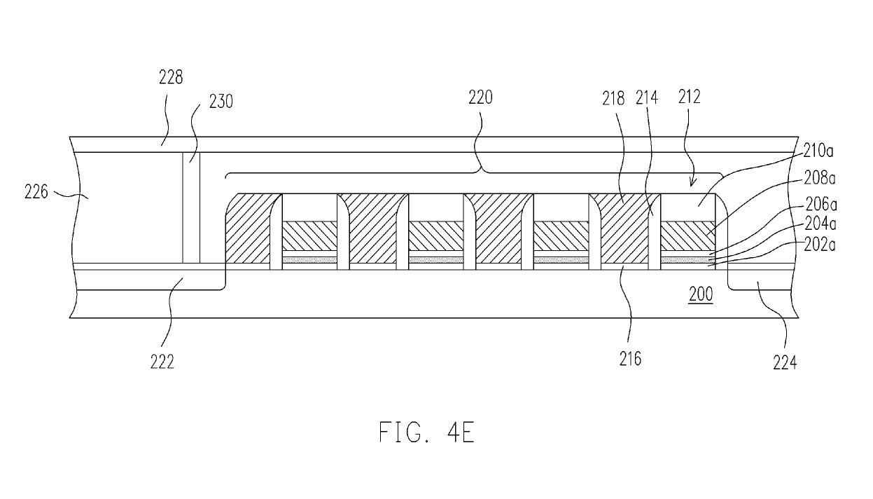

FIGS. 4A through 4E are schematic cross-sectional view along line A-A′ of FIG. 2A showing the steps for fabricating a NAND type non-volatile memory according to one preferred embodiment of the present invention. First, as shown in FIG. 4A, a substrate 200 such as a silicon substrate having a device isolation structure (not shown) thereon is provided. Thereafter, a dielectric layer 202, a charge-trapping layer 204 and a dielectric layer 206 are formed over the substrate 200 sequentially. The dielectric layer 202 can be a silicon oxide layer having a thickness between about 20 Å to 30 Å, for example. The dielectric layer 202 is formed, for example, by performing a thermal oxidation process. The charge-trapping layer 204 can be a silicon nitride layer having a thickness between about 30 Å to 50 Å, for example. The charge-trapping layer is formed, for example, by performing a chemical vapor deposition process. The dielectric layer 206 can be a silicon oxide layer having a thickness between about 20 Å to 40 Å, for example. The dielectric layer 206 is formed, for example, by performing a chemical vapor deposition process. Obviously, the dielectric layer 202 and the dielectric layer 206 can be formed by other materials that have similar properties. Furthermore, the charge-trapping layer 204 is not limited to a silicon nitride layer. The charge-trapping layer 204 can also be formed by tantalum oxide, strontium titanate or hafnium oxide, for example.

As shown in FIG. 4B, a conductive layer 208 and a cap layer 210 are formed over the substrate 200 in sequence. The conductive layer 208 can be a doped polysilicon layer, for example. The conductive layer 208 is formed, for example, by depositing an undoped polysilicon layer in a chemical vapor deposition process and implanting ions into the polysilicon layer thereafter. The cap layer 210 is a silicon oxide layer, for example. The cap layer 210 is formed, for example, by performing a chemical vapor deposition process using tetra-ethyl-ortho-silicate (TEOS)/ozone (O3) as the reactive gases.

As shown in FIG. 4C, the cap layer 210, the conductive layer 208, the dielectric layer 206, the charge-trapping layer 204 and the dielectric layer 202 are patterned to form a plurality of gate structures 212 including a cap layer 210a, a conductive layer 208a, an upper dielectric layer 206a, a charge-trapping layer 204a and a bottom dielectric layer 202a. The conductive layer 208a serves as a control gate in the memory cell.

Thereafter, spacers 214 are formed on the respective sidewalls of the gate structures 212. The spacers 214 are formed, for example, by depositing insulating material over the substrate 200 and performing an anisotropic etching operation such that only the insulating material layer on the sidewalls of the gate structures 212 is retained.

As shown in FIG. 4D, a select gate dielectric layer 216 is formed over the substrate 200. The select gate dielectric layer 216 can be a silicon oxide layer having a thickness between about 160 Å to 170 Å. The select gate dielectric layer 216 is formed, for example, by performing a thermal oxidation process. Thereafter, a select gate 218 is formed on one side of each gate structure 212. The select gates 218 are formed, for example, by depositing a material into the space between adjacent gate structures 212 so that the gate structures 212 are serially connected together. To form the select gates 218, a conductive layer (not shown) is formed over the substrate 200 such that the conductive layer completely fills the space between neighboring gate structures 212. Thereafter, a portion of the conductive layer is removed to expose the cap layer 210a. Next, a mask layer (not shown) is formed over the substrate 200 to cover the area for forming the memory cell row 220 is formed over the substrate 200. Then, the gate structures 212 outside the area for forming the memory cell row 220 or a portion of the conductive layer is removed. Finally, the mask layer is removed.

As shown in FIG. 4E, an ion implantation is carried out to form a source region 224 and a drain region 222 in the substrate 200 on each side of the memory cell row 220. The source region 224 is formed in the substrate 200 beside the gate structure 212 on one side of the memory cell row 220. The drain region 226 is formed in the substrate 200 beside the select gate 218 on one side of the memory cell row 220. Thereafter, an inter-layer dielectric layer 226 is formed over the substrate 200. A plurality of plugs 230 is formed in the inter-layer dielectric layer 226 to connect with the drain region 222 electrically. Finally, a conductive line 228 (a bit line) electrically connecting with the plug 230 is formed over the inter-layer dielectric layer 226. Since remaining steps for fabricating the memory cell array should be familiar to those skilled in the technique, detailed description is omitted.

In the aforementioned embodiment, the charge-trapping layer 204 serves as a storage unit for electrical charges and hence the gate-coupling ratio is no longer critical. Thus, the memory cell can have a lower operating voltage and a higher operating speed. Furthermore, the process of fabricating the non-volatile memory in the present invention is much simpler than the conventional process so that the production cost is reduced.

In the aforementioned embodiment, four memory cells are serially connected together. However, the actual number of serially connected memory cells may vary according to circumstances. For example, a total of 32 to 64 memory cells may be serially connected along the same bit line. Furthermore, the method of fabricating the non-volatile memory according to the present invention is particularly suitable for producing memory cell arrays.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a non-volatile memory, comprising the steps of:
providing a substrate;
forming a plurality of gate structures on the substrate, wherein each gate structure comprises, from the substrate, a bottom dielectric layer, a charge-trapping layer, an upper dielectric layer, a control gate and a cap layer;
forming a plurality of spacers on the sidewalls of the gate structures;
forming a select gate dielectric layer over the substrate;
forming a plurality of select gates on each side of the gate structures such that the gate structures are serially connected together to form a memory cell row;
forming a source/drain region in the substrate on each side of the memory cell row; and
forming a bit line over the substrate to electrically connect with the drain region.

2. The method of claim 1, wherein the step of forming the gate structure over the substrate further comprises:
forming a first dielectric layer over the substrate;
forming a charge-trapping material layer over the first dielectric layer;
forming a second dielectric layer over the charge-trapping layer;
forming a first conductive layer over the second dielectric layer;
patterning the first conductive layer to form the control gate; and
patterning the second dielectric layer, the charge-trapping material layer, the first dielectric layer to form the upper dielectric layer, the charge-trapping layer and the bottom dielectric layer.

3. The method of claim 1, wherein material constituting the charge-trapping layer comprises silicon nitride.

4. The method of claim 1, wherein the step of forming the select gate dielectric layer over the substrate comprises performing a thermal oxidation process.

5. The method of claim 1, wherein the step of forming the select gates on etch side of the gate structures comprises:
forming a second conductive layer over the substrate, wherein the second conductive layer completely fills the space between the gate structures; and
removing the gate structures and a portion of the second conductive layer disposed outside the area for forming the memory cell row.

6. The method of claim 1, wherein the step of forming the source region/drain region in the substrate on each side of the memory cell row comprises performing an ion implantation process.

7. The method of claim 1, wherein material constituting the charge-trapping layer comprises silicon nitride.

8. The method of claim 1, wherein material constituting the bottom dielectric layer and the upper dielectric layer comprises silicon oxide.
